(19) United States
(12) Patent Application Publication
(10) Pub. No.: US 2025/0353038 A1
(43) Pub. Date: Nov. 20, 2025

(54) Heterogenous Assembly of Sensor Arrays

(71) Applicant: Tacta Systems Inc., Palo Alto, CA (US)

(72) Inventors: Evan Cate, Palo Alto, CA (US); Andreas Bibl, Los Altos, CA (US); Patrick M. Smith, San Jose, CA (US); Dariusz Golda, Portola Valley, CA (US)

(21) Appl. No.: 18/666,188

(22) Filed: May 16, 2024

(51) Int. Cl. B06B 1/06; G08B 6/00; H10N 39/00

(52) U.S. Cl. CPC B06B 1/0622; B06B 1/0666; H10N 39/00; G08B 6/00

(57) ABSTRACT

Sensor assemblies, sensor array transfer sequences, and methods of assembly are described. The sensors can include sensor dies as well as sensor packages including stacked sensor dies and IC dies.

### BACKGROUND

### Field

Embodiments described herein relate to sensor arrays, and more particularly to the transfer and integration of sensor arrays.

### Background Information

Tactile sensor arrays continue to attract attention due to a variety of potential applications such as human-machine interaction, robotics, wearable healthcare devices, and augmented/virtual reality. Generally, the sensor arrays can be arranged in certain geometric configurations or patterns to collect information over a wide area and in multiple dimensions of an environment. Sensing over a large area can be particularly important for realizing artificial tactile sensations. A variety of types of sensors can be implemented depending upon the particular application. For example, piezoelectric sensors can utilize the piezoelectric effect to detect changes in pressure, acceleration, temperature, or strain by converting such detections to an electrical charge. In another example, capacitive sensors can utilize capacitive sensing to detect an object in proximity that may be conductive or may have a dielectric constant that is different from air.

A variety of techniques can be implemented to realize sensor arrays, such as forming capacitors or piezoresistive material arrays directly onto a substrate, lamination, or alternatively transferring discrete sensors or arrays of sensors to a substrate. For example, conventional pick and place tools use a vacuum chuck to hold individual devices that are diced from a wafer. If the individual devices are too small, at a certain point vacuum cannot overcome the adhesion of the backing tape holding the devices post dicing.

### SUMMARY

Sensor assemblies, sensor array transfer sequences, and methods of assembly are described. In an embodiment a sensor assembly includes an article, such as a glove, sleeve, or other wearable device, and a sensor array coupled with the article. The sensor array can include a plurality of sensor dies, or sensor packages including a stacked sensor die and integrated circuit (IC die). In the case of a sensor package, the IC die may include a top side and a back side, and the sensor die may be bonded to the top side of the IC die. In accordance with embodiments the sensor die can include a diaphragm that is deflectable toward a cavity between the IC die and the sensor die. The sensor die may additionally include a strain response material layer on the diaphragm, and between the diaphragm and the IC die. For example, the strain response material layer can be a piezoelectric material layer, a dielectric material layer for capacitive sensing, or strain gauge material layer such as a metal trace or pattern. The IC die may additionally include analog front end (AFE) circuitry to amplify and filter analog signals derived from the strain response material layer upon deflection of the diaphragm, and an analog to digital converter (ADC). In accordance with embodiments, the sensor die may include a plurality of electrical contact terminals (e.g., pillars) bonded to a corresponding plurality of electrical contact terminals (e.g., landing pads) of the IC die, where the plurality of electrical contact terminals of the sensor die extend through a thickness of a patterned underfill material that bonds the sensor die to the IC die and defines perimeter edges 151 of the cavity between the sensor die and the IC die. A second plurality of electrical contact terminals (e.g., landing pads) of the IC die can also be located laterally outside of the patterned underfill material. Additionally, the IC die may have a larger footprint than the sensor die.

In accordance with embodiments the transfer sequences can be facilitated by suspending the sensors (e.g., sensor dies, sensor packages) over cavities in a donor substrate with a plurality of tethers, and breaking the tethers during the transfer sequence to release the sensors. In an embodiment, each transferred sensor die can include a resulting plurality of cleaved tether nubs connected to the diaphragm. Each diaphragm can include a perimeter edge with a perimeter surface texture spanning the perimeter edge, and each cleaved tether nub can include a terminal end with a terminal end surface texture that is different from the perimeter surface texture, due to different manners of formation.

In an embodiment a donor substrate includes a support substrate that includes a pattern of anchors and a plurality of cavities with cavity sidewalls defined by the pattern of anchors. A plurality of sensors (e.g., sensor dies, sensor packages) can be suspended over the plurality of cavities with a plurality of tethers that extend from the plurality sensors and connect to the pattern of anchors. In an embodiment, an array of diaphragms and the plurality of tethers can be formed in a support layer that spans over the support substrate, with each sensor including a corresponding diaphragm. A variety of materials systems can be leveraged to fabricate the donor substrates, sensor dies and IC dies. In some embodiments silicon and silicon-on-insulator (SOI) wafers are utilized. For example, the support substrate and support layer can both include silicon from silicon or SOI wafers. Each sensor that is supported on a donor wafer may include a strain response material layer over a corresponding diaphragm, and a plurality of electrical contact terminals that protrude away from the diaphragm and above the strain response material layer. A patterned underfill material may also be provided on the diaphragm, laterally surrounding the plurality of electrical contact terminals. In some embodiments donor wafers are fabricated that support an array of sensor dies. In some embodiments donor wafers are fabricated that support an array of IC dies. In some embodiments an IC die donor wafer can be bonded to a sensor die donor wafer, followed by releasing of the IC dies onto the sensor dies to form a donor wafer include sensor packages of stacked IC dies and sensor dies.

In an embodiment, a method of forming a sensor array includes bonding an array of integrated circuit (IC) dies supported on an IC die donor substrate to a plurality of sensor dies supported on a sensor die donor substrate, releasing the plurality of IC dies onto the plurality of sensor dies, and etching a release layer on the sensor die donor substrate to remove the release layer from a plurality of cavities underneath the plurality of sensor dies. In accordance with embodiments, etching the release layer is performed with a vapor etch process.

In an embodiment, a sensor array transfer sequence includes securing a back side of a donor substrate to a vacuum chuck where a front side of the donor substrate includes a plurality of sensors suspended above a plurality of cavities in the donor substrate with a plurality of tethers, translating the vacuum chuck over a receiving substrate, contacting the receiving substrate with the plurality of sensors, and breaking the plurality of tethers to release the plurality of sensors onto the receiving substrate. In some embodiments each sensor includes a sensor die. In some embodiment, each sensor is a sensor package that includes a sensor die and IC die, where each sensor die includes a diaphragm that is deflectable toward a cavity between the IC die and the sensor die.

### BRIEF DESCRIPTION OF THE DRAWINGS

FIG. 1 is a schematic layout view illustration of a sensing system in accordance with an embodiment.

FIG. 2A is a schematic layout view of a sensor array connected to a local controller.

FIG. 2B is a schematic layout view of a sensor array including integrated sensor packages with separate connection in accordance with an embodiment.

FIG. 2C is a schematic layout view of a sensor array including integrated sensor packages with serial connection in accordance with an embodiment.

FIG. 3 is a system diagram for a serially connected sensor array of FIG. 2C in accordance with an embodiment.

FIG. 4A is a schematic cross-sectional side view illustration of a sensor die donor substrate in accordance with an embodiment.

FIGS. 4B-4C are schematic top view illustrations of sensor dies supported on a donor substrate with a plurality of tethers in accordance with embodiments.

FIG. 5 is a schematic cross-sectional side view illustration of a plurality of diced sensor die donor substrates in accordance with an embodiment.

FIGS. 6-11A are schematic cross-sectional side view illustration of a sensor die array transfer sequence in accordance with an embodiment.

FIGS. 11B-11C are schematic top view illustrations of the diaphragm of an IC die and fractured tethers in accordance with embodiments.

FIG. 12A is a schematic cross-sectional side view illustration of a sensor die donor substrate in accordance with an embodiment.

FIGS. 12B-12C are schematic top view illustrations of sensor dies supported on a donor substrate with a plurality of tethers in accordance with embodiments.

FIG. 13 is a schematic cross-sectional side view illustration of an IC die donor substrate in accordance with an embodiment.

FIG. 14 is a schematic cross-sectional side view illustration of an IC die donor substrate bonded to a sensor die donor substrate in accordance with an embodiment.

FIG. 15 is a schematic cross-sectional side view illustration of an array of IC dies bonded to a plurality of sensor dies to form a sensor package donor substrate in accordance with an embodiment.

FIG. 16A is a schematic cross-sectional side view illustration of a plurality of diced sensor package donor substrates in accordance with an embodiment.

FIG. 16B is a schematic cross-sectional side view illustration of a plurality of diced sensor package donor substrates in accordance with an embodiment.

FIGS. 17-23A are schematic cross-sectional side view illustration of a sensor package array transfer sequence in accordance with an embodiment.

FIGS. 23B-23C are schematic top view illustrations of the diaphragm of an IC die of a sensor package and fractured tethers in accordance with embodiments.

FIG. 24A is schematic cross-sectional side view illustration of sensor package with fractured tethers and face up IC die in accordance with embodiments.

FIGS. 24B-24C are schematic top view illustrations of the diaphragm and fractured tethers of a sensor die superimposed over an IC die of a sensor package in accordance with embodiments.

### DETAILED DESCRIPTION

Embodiments describe sensor arrays, donor substrates including sensor arrays, and methods of transfer of sensor arrays to one or more receiving substrates. The transfer processes in accordance with embodiments can transfer sensors from a high-density donor substrate to a lower density receiving substrate. The processes can be used where manufacture of the sensors at high densities provides cost savings, with subsequent reduction in density on the receiving substrates allowing multiple receiving substrates to be populated from a given donor substrate. This can allow for independent manufacture of the sensors and receiving substrates with different manufacturing techniques and materials.

In one aspect, embodiments describe donor substrates and sensor array transfer sequences in which high densities of sensor arrays are fabricated so that they can be readily transferred to a receiving substrate utilizing conventional pick and place equipment, which can reduce overall cost of integration. In an exemplary sensor array transfer sequence, the back surface of a donor substrate can be held with a conventional vacuum chuck, where a high-density array of sensors is secured to an opposite surface of the donor substrate with an arrangement of tethers than can be broken during placement of the sensors onto one or more receiving substrates. It is to be appreciated that while transfer sequences are described with regard to vacuum chucks, that embodiments can be implemented with a variety of transfer tools.

The sensor array transfer sequences described herein can be applied to a variety of sensors and may be applicable to devices other than sensors. The sensors in accordance with some embodiments can be diaphragm-type pressure sensors (or transducers) in which an integrated diaphragm can be deflected during operation. Deflection in turn can transfer stress to a strain response material layer from which an electrical charge is measured. For example, the strain response material layer can be a piezoelectric material layer, a dielectric material layer for capacitive sensing, or strain gauge material layer such as a metal trace or pattern. The sensors described herein can be discrete sensor dies or may be sensor packages in which a sensor die is stacked on top of an additional integrated circuit (IC) die for signal conditioning. For example, the IC die may include circuitry such as analog front end (AFE) circuitry and/or an analog to digital controller (ADC). Such a stacked configuration can reduce overall area, integrate the diaphragm configuration into the stacked configuration, and reduce distance between the IC die and sensor die, potentially reducing latency and signal loss.

In another aspect, it has been observed that sensor requirements for certain tactile sensing applications used to replicate human-scale tactile sensing, touch, grasp and/or dexterity can require fine pitch sensor arrays and highly sensitive sensors. For example, humans can resolve objects as being spatially separate when they are ≥2 mm apart (e.g., Meissner corpuscles at the fingertips). As such, the sensor array disclosed herein may include sensors configured at 2× this spatial frequency (e.g., 1 mm pitch) or more, enabling the sensor array to also resolve objects that are 2 mm spacing (or less). In accordance with embodiments, the sensors may have lateral dimensions, for example, in a range of 100 to 1,000 μm, or more specifically, 100 to 300 μm, per side edge. Sample rate of the sensors (e.g., via controllers and/or other circuitry) can be at a rate that is faster than humans performing the tasks, and dynamic ranges of the sensors may exceed that of human touch. It has been additionally observed however, that both sensors and readout circuitry coupled with the sensors can be susceptible to significant parasitic effects. In accordance with some embodiments, integrated sensor packages can include both a sensor die and an IC die for signal conditioning. The IC die may include circuitry such as AFE circuitry and/or an ADC and may additionally include address circuitry to define unique addresses for each sensor in the sensor array. In highly sensitive applications requiring precise coordination of various sensors, such as tactile sensor arrays, the AFE circuitry may amplify and filter the analog signals derived from the sensor die for processing by the ADC, thereby increasing signal strength and reducing noise. The ADC converts the analog signals to digital signals. Integration of AFE and/or ADC circuitry close to each sensor die may reduce latency and signal loss, facilitating sensitivity necessary to replicate human-scale tactile sensing.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

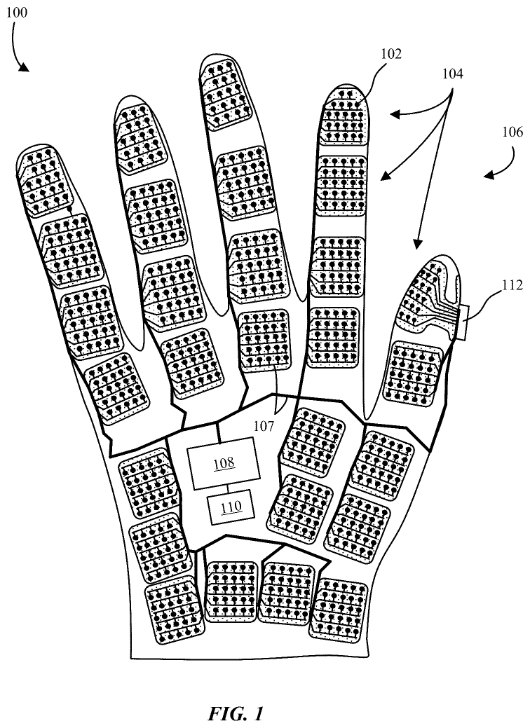

FIG. 1 is an example of a sensing system 100 including a plurality of sensors 102 integrated into a plurality of sensor arrays 104. The sensing system 100 may perform an integrated readout of sensors 102 as described herein. The sensor arrays 104 may be integrated with an article 106 which may be deformable and/or have relatively limited space. For example, the sensing system 100 may be a wearable system that is integrated with a sensing glove worn by a user. The sensor arrays 104 may include, for example, 1,000 sensors, 10,000 sensors, or more, integrated with the article 106. Each sensor array 104 may correspond to a group of sensors 102 arranged in a location of the article 106. For example, a first sensor array 104 may correspond to a first group of 10 sensors, 100 sensors, or more, arranged at a first finger or fingertip of the sensing glove, a second sensor array 104 may correspond to a second group of 10 sensors, 100 sensors, or more, arranged at a second finger or fingertip of the sensing glove, and so forth.

The sensing system 100 may include a controller 108 (another IC, such as an application-specific integrated circuit (ASIC) or field-programmable gate array (FPGA)) connected to sensors 102 of the plurality of sensor arrays 104 and to a communications device 110. For example, the sensors 102 could be on a palmar side of a sensing glove, and the controller 108 and the communications device 110 could be on the palmar side or a dorsal side of the sensing glove. The controller 108 may connect directly and/or indirectly to the sensors 102. For example, in some cases, the controller 108 may connect directly to sensors 102, and in other cases, the controller 108 may be a global controller connected to one or more local controllers that are connected to the sensors 102. For example, the controller 108 could connect to a local controller 112 (e.g., another IC, such as an ASIC or FPGA) arranged on a section of the article 106 (e.g., a dorsal side of a thumb of the sensing glove). The local controller 112, in turn, may connect to sensors 102 of one or more sensor arrays 104 in the section (e.g., the thumb). The local controller 112 can process outputs (e.g., digital outputs) from sensors 102 in the section to generate a compressed bitstream for the controller 108. In some implementations, the controller 108 may be a hybrid controller operating as both a global controller (e.g., connected to local controllers arranged in some sections of the article 106) and a local controller (e.g., connected directly to sensors 102 in other sections of the article 106).

In operation the controller 108 can cause one or more sensors 102 of one or more sensor arrays 104 to each transmit an output. In some cases, the controller 108 can directly cause transmission of an output from a sensor 102, such as by sending an input to trigger a sensor 102. In other cases, the controller 108 can indirectly cause transmission of an output from a sensor 102, such as by causing a local controller to send an input to trigger a sensor 102, and/or by causing one sensor 102 to send an output to trigger another sensor 102.

The communications device 110 may enable transmission of a collection of data from sensors 102 to another system. The communications device 110 may utilize wired or wireless connections, such as universal serial bus (USB), low-voltage differential signaling (LVDS), serial peripheral interface (SPI), Bluetooth, or Ethernet, to transmit the digital data. For example, the controller 108 can receive outputs from the sensors 102 based on triggering those sensors, then utilize the communications device 110 to transmit a compressed bitstream encoding the outputs to another system, such as a host computer or server. As a result, the controller 108 can selectively perform readout of sensors 102 of sensor arrays 104 in the sensing system 100 to obtain sensing information relatively fast and with high resolution.

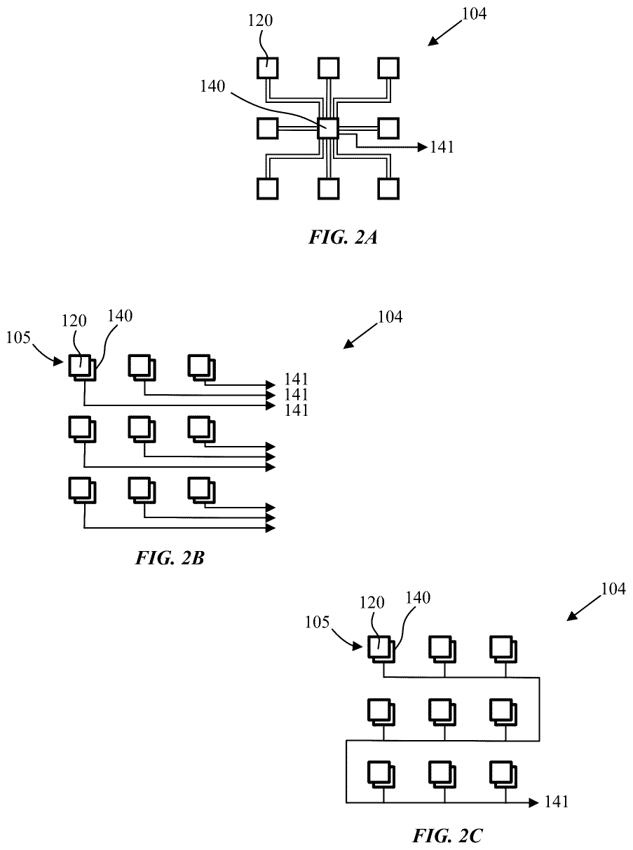

Referring now to FIG. 2A a schematic layout view illustration is provided of a sensor array 104 including a plurality of sensors dies 120 coupled to an IC die 140 for signal conditioning. The IC die 140 may include circuitry such as AFE circuitry and/or an ADC and may additionally include address circuitry to define unique addresses for each sensor in the sensor array. As shown, the IC die 140 may include a data output 141, for example along interconnect 107, for connection with controller 108 and/or local controller 112. In the arrangement illustrated in FIG. 2A, the IC die may receive analog inputs from each of the sensor dies 120, perform analog conditioning with the AFE circuitry, analog-to-digital conversion with the ADC, and addressing for each IC die in the group, and generate a serial bit stream (corresponding to the sensor readings) as a digital output at data output 141. The data outputs 141 for sensor arrays 104 can be coupled directly to corresponding local controllers 112 or can be grouped in a bus line for connection with controller 108.

FIG. 2B is a schematic layout view of a sensor array including integrated sensor packages 105 with separate connection in accordance with an embodiment. In such a configuration the sensors 102 (e.g., as shown in FIG. 1) may be sensor packages including stacked sensor dies 120 and IC dies 140 for signal conditioning. This may enable each sensor in the sensor array 104 to convert the sensor's analog signals into a digital representation (e.g., the digital output) in a single integrated device. The data outputs 141 for sensor packages 105 can be grouped in a bus line for connection with controller 108 or local controller 112.

FIG. 2C is a schematic layout view of a sensor array including integrated sensor packages 105 with serial connection in accordance with an embodiment. In such a configuration the sensors 102 (e.g., as shown in FIG. 1) may be sensor packages including stacked sensor dies 120 and IC dies 140 for signal conditioning. Furthermore, the IC dies 140 may additionally include address circuitry to define unique addresses for each sensor in the sensor array. As shown, the IC dies 140 can be serially connected with data output 141 and generate a serial bit stream (corresponding to the sensor readings).

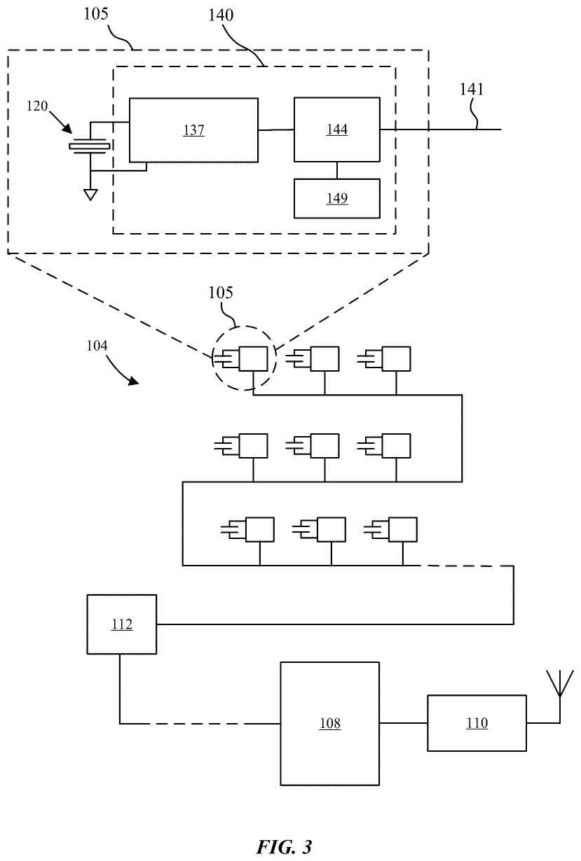

Referring now to FIG. 3, a system diagram is provided for a serially connected sensor array of FIG. 2C in accordance with an embodiment. It is to be appreciated that while the system diagram of FIG. 3 is specific with regard to the arrangement of FIG. 2C, that various components illustrated in FIG. 3 are common to other arrangements disclosed herein, and modifications to the system diagram illustrated are envisioned in order to meet requirements of alternative configurations. As shown in the particular configuration illustrated in FIG. 3, each sensor in a sensor array 104 may include a sensor package 105 including stacked sensor dies 120 and IC dies 140. Furthermore, each IC die 140 can include AFE circuitry 137, an ADC 144 and optionally an address circuitry 149.

In operation, a controller (e.g., the controller 108 and/or the local controller 112) can cause the sensor packages 105 to each transmit a digital output indicating sensing in response to receiving a digital input. Initially, a pulse of the digital input from the controller can trigger a first sensor to perform a measurement and generate a digital output that may be read by the controller. After that measurement is performed, with the digital output sent to the controller, the first sensor (operating as an upstream sensor) can then trigger a second sensor (operating as a downstream sensor) to perform a next measurement and generate a next digital output that may be read by the controller. This process may continue as additional downstream sensors of the sensor array receive digital inputs from upstream sensors to cause the downstream sensors to perform measurements and generate digital outputs. The controller can read the digital outputs from the sensors (sensor packages), sequentially, one after another, in the order of the sensors in the connected series.

In some implementations, the controller may be a local controller (e.g., the local controller 112) that triggers the sensors. The local controller can then generate a first compressed bitstream, comprised of digital outputs from the sensors, for a global controller (e.g., the controller 108). The global controller, in turn, can utilize the communications device 110 to send a second compressed bitstream including the first compressed bitstreams from one or more local controllers in the sensing system 100.

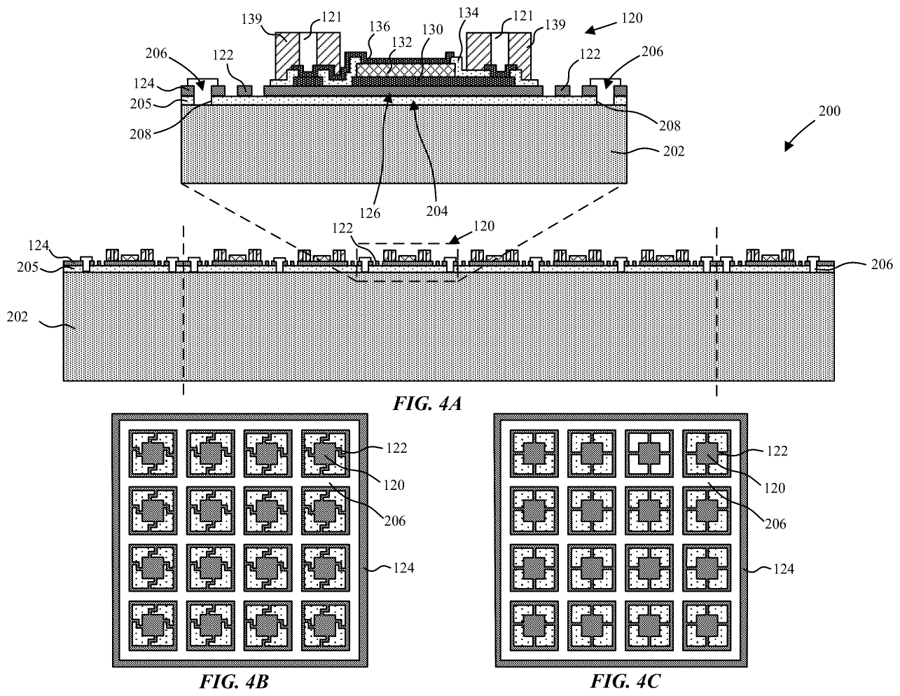

Referring now to FIGS. 4A-4C, FIG. 4A is a schematic cross-sectional side view illustration of a sensor die 120 donor substrate 200 in accordance with an embodiment; FIGS. 4B-4C are schematic top view illustrations of sensor dies 120 supported on a donor substrate 200 with a plurality of tethers 122 in accordance with embodiments.

As shown, the donor substrate 200 can include a support substrate 202 including an array of anchors 206 and a plurality of cavities 204 with cavity sidewalls 208 defined by the pattern of anchors 206. As shown in FIG. 4A, a release layer 205, such as silicon oxide, can fill the cavities 204, for example, to provide support during manufacture of a sensor die, and optional subsequent processing. The release layer 205 may be a sacrificial layer that is later removed. Removal of the release layer can form the cavities, of which their perimeters (or cavity sidewalls 208) may be defined by the arrangement of anchors 206. For example, the anchor 206 patterns can be a variety of shapes including horizontal and/or vertical streets, discrete bollards, etc. In the particular embodiment illustrated the anchors include a plurality of horizontal and vertical streets forming a grid around a plurality of diaphragms 126 connected to the anchor 206 pattern with tethers 122. A plurality of sensor dies 120 can be suspended over the plurality of cavities 204. For example, there may be one sensor die 120 per cavity 204. This may be accomplished with a plurality of tethers 122 extending from the plurality of sensor dies 120 and connected to the anchors 206 to suspend the plurality of sensor dies 120 over the plurality of cavities 204. In the illustrated embodiment, a support layer 124 spans over the support substrate 202. The support layer 124 may include an array of diaphragms 126 and the plurality of tethers 122, where each sensor die 120 includes a diaphragm 126. As shown in FIGS. 4B-4C, the tethers 122 can assume a variety of configurations, such as straight cantilever-type bars, or include multiple turns. The tethers 122 can be designed to break during a sensor die transfer sequence, and may include notches or other structures to facilitate breaking.

The support substrate 202 and support layer 124 can be formed of a variety of materials, including glass, ceramics, silicon, etc. In accordance with embodiments wafer-level processing with silicon-based wafers can be used to leverage existing equipment and materials systems. For example, the support substrate 202 can be a silicon substrate. Likewise the support layer 124 can be a silicon layer, such as a thinned silicon substrate or device layer of a silicon-on-insulator (SOI) substrate. The cavities 204 can be formed using a variety of techniques including etching into silicon substrates, or selective removal of oxide layer(s) such as a buried oxide layer in an SOI substrate. Likewise, the pattern of anchors 206 can be formed from silicon layers, or be selectively deposited polysilicon, metal or other material. In an embodiment, the anchors 206 are formed by etching of openings through the support layer 124 and an underlying (sacrificial) release layer 205 to the support substrate 202. For example, the support layer and release layer may be the device layer and buried oxide layer in an SOI substrate, which are patterned for form openings followed by deposition (or growth) of the anchors 206. In an embodiment, the anchors 206 are formed of a metal (e.g. copper, gold, etc.) formed using a plating technique. A variety of sequences can be used to fabricate the support substrate 202, anchors 206 and support layer 124. As shown in FIG. 4A, a release layer 205, such as silicon oxide, can fill the cavity 204, for example, to provide support during manufacture of a sensor die, and optional subsequent processing. The release layer 205 may be a sacrificial layer that is later removed.

Each sensor die 120 can be formed by depositing a bottom electrode layer 130, which may be a multi-layer metal stack, followed by a strain response material layer 132 over the bottom electrode layer 130. Suitable piezoelectric materials for the strain response material layer 132 may include ceramics, wide bandgap semiconductors or polymers. Exemplary materials include lead zirconate titanate (PZT), barium titanate, and lead titanate, gallium nitride, zinc oxide, and polyvinylidene fluoride (PVDF).

An insulator layer 134, such as alumina or a nitride, can then be formed over the underlying structure and patterned to prevent shorting with subsequent conductive materials, such as top electrode layer 136, which may also be a multi-layer metal stack. In some embodiment, the insulator layer 134 may be formed of a different material than the release layer 205 so that the insulator layer is not removed during etching of the release layer 205. The top electrode layer may cover a top surface of the strain response material layer 132 so that the strain response material layer 132 is sandwiched between the bottom electrode layer 130 and the top electrode layer 136. It is to be appreciated that while the particular configuration illustrated can be for a piezoelectric strain response material layer, that a similar configuration can be utilized for capacitive sensing. A sandwich configuration may not be needed for strain gauge configurations, where the bottom electrode layer 130 and top electric layer 136 can be replaced with suitable electrode terminals at ends of a metal trace or pattern.

Electrical contact terminals 121 may then be formed. For example, this may be accomplished by electroplating multiple metal layers. As shown, the electrical contact terminals 121 may be vertical interconnects, and pillar-shaped. As will become apparent in the following description, the insulator layer 134 may be protected during removal of the release layer(s). This may be accomplished by forming the insulator layer 134 of a different material than the release layer(s). As shown in FIG. 4A, the plurality of electrical contact terminals 121 may protrude away from the diaphragm 126, and protrude above the strain response material layer 132, as well as any other layers. The electrical contact terminals 121 may extend furthest away from the diaphragm 126 to allocate space beneath the diaphragm when transferred to a receiving substrate, though this can also be facilitated by the bonding surface on the receiving substrate. In some embodiments, a photo-definable underfill material 139 (e.g., wafer-level underfill (WLUF) material) can optionally be formed completely around a perimeter of the sensor die 120. The photo-definable underfill material 139 may be a polymer material, and may be B-staged at this stage in the manufacturing sequence. The photo-definable underfill material 139 may be used to provide both mechanical connection and support of the diaphragm 126 area, and also for sealing of the structure from outside environment. As shown, the patterned underfill material 139 can be on the diaphragm 126 and laterally surrounding the plurality of electrical contact terminals 121 both inside and out. Such a configuration may facilitate both sealing and bonding of the sensor die simultaneously, and also provide structural support for the flexible diaphragm configuration of the sensor after transfer and product integration. In some embodiments, the photo-definable underfill material 139 may extend furthest away from the diaphragm 126 and cover the bonding surfaces of the electrical contact terminals 121. In such a configuration, the electrical contact terminals 121 can punch through the photo-definable underfill material 139 during a transfer sequence prior to final cure. A photo-definable underfill material 139 can also, or alternatively, be formed on a receiving substrate as opposed to the sensor die 120 structure to facilitate sealing as well as bonding.

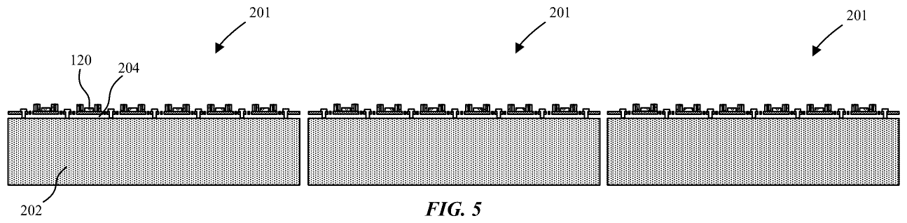

The donor substrate 200 shown in FIG. 4A can be fabricated at both a panel-level or wafer-level using suitable processing techniques. The donor substrate 200 can then be diced to form a plurality of smaller donor substrates 201, or macro dies, as shown in FIG. 5. Size may be determined by the chuck, or collet, size of a transfer head assembly such as a vacuum chuck assembly. Size can also be a function of final sensor array size to be transferred, or sensor array 104 size. Prior to, or after singulation of the donor substrate 200 into multiple smaller donor substrates 201, the release layer 205 can be removed, such that the plurality of sensor dies 220 are suspended above the cavities 204 with only the tethers 122. Suitable etching techniques, such as wet etching or vapor etching may be utilized. In a particular embodiment where the release layer 205 is formed of silicon oxide a vapor hydrofluoric acid (HF) operation may be performed to remove the release layer 205.

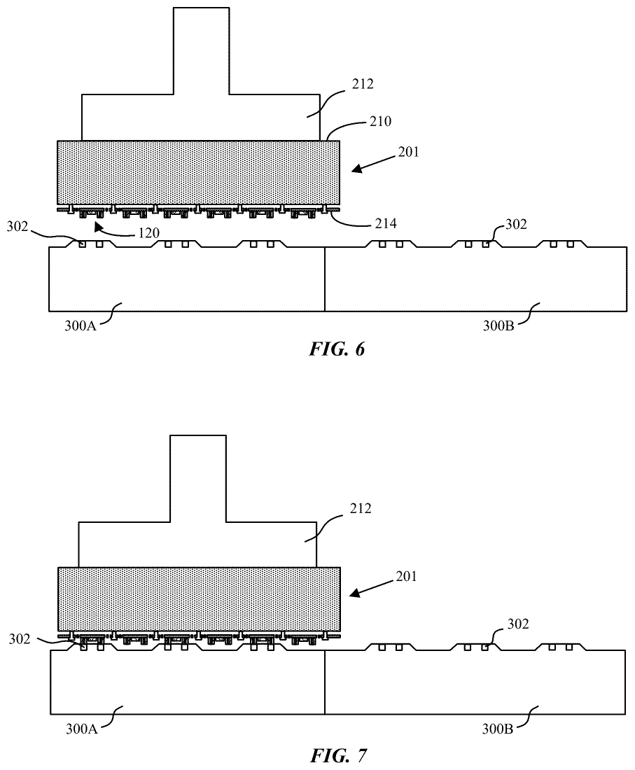

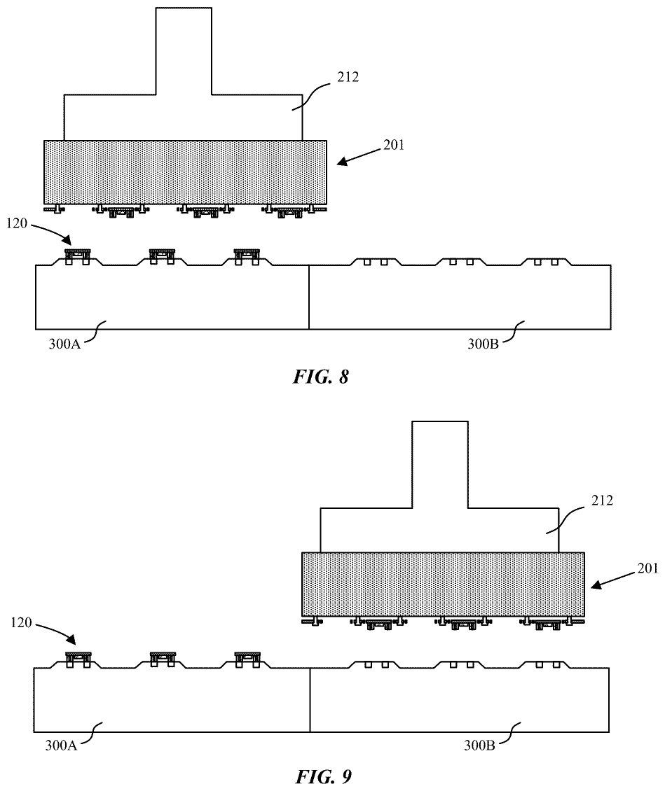

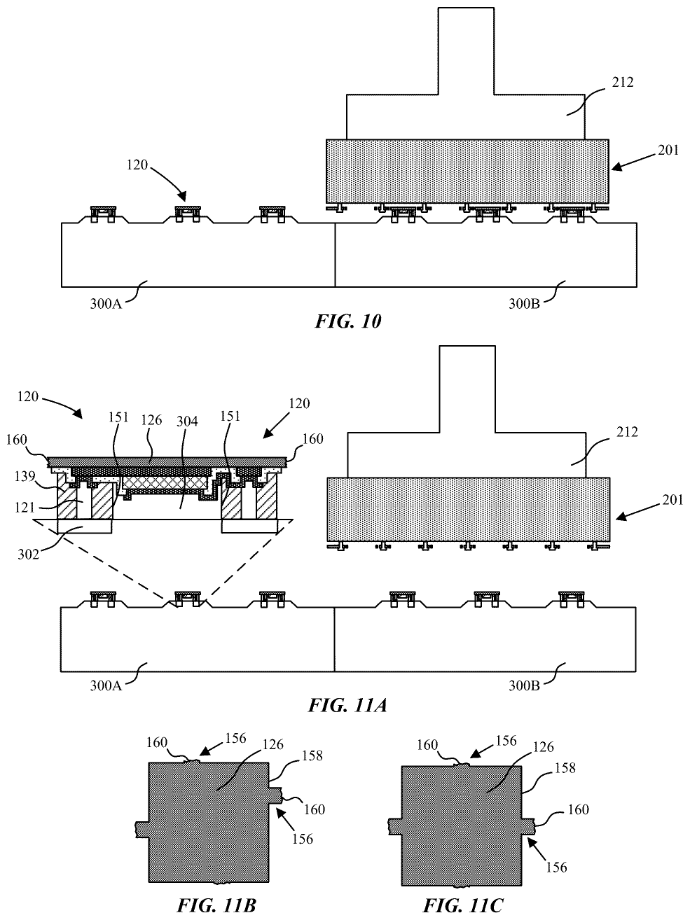

FIGS. 6-11A are schematic cross-sectional side view illustration of a sensor die array transfer sequence in accordance with an embodiment. As shown in FIG. 6, a back side 210 of a donor substrate, such as the diced donor substrate 201, can be secured to a vacuum chuck 212 (e.g., collet) so that a front side 214 of the donor substrate 201 includes a plurality of sensor dies 120 suspended above a plurality of cavities in the donor substrate with a plurality of tethers. The vacuum chuck 212 can then be translated over a receiving substrate 300A. The receiving substrate 300A is then contacted with at least a portion of the plurality of sensor dies 120. As shown in FIG. 7, the receiving substrate 300A may include a plurality of landing terminals 302 upon which the contact terminals 121 of the sensor dies may be placed to provide electrical connection. Additionally, only a portion of the sensor dies 120 may be contacted with the receiving substrate 300A. The landing terminals 302 may stand proud, extending from the receiving substrate 300A, or may be flush with a top surface of the receiving substrate 300A. A variety of surface contours may be utilized to facilitate multiple transfers. Where the landing terminals 302 stand proud, they may have an area sufficient to accept both the electrical contact terminals 121 and photo-definable underfill material 139 for each sensor 120. Where the landing terminals 302 are flush with the top sides of elevated platforms the landing terminals 302 may not need to also have a width necessary to accept the photo-definable underfill material 139, as this may be provided by the top sides of the elevated platforms of the receiving substrate. In accordance with embodiments, pressure applied by the vacuum chuck 212 and opposing force pressure of the receiving substrate 300A can cause the plurality of tethers 122 connected to the contacted sensor dies 120 to break, releasing the portion of the plurality of sensor dies 120 onto the receiving substrate 300A. This may be accompanied by the application of heat to the donor substrate 201 while contacting the receiving substrate with the plurality of sensor dies. For example, this can be with a heater connected to the vacuum chuck 212. Heat may also be applied through the receiving substrate 300A, or from an alternative source. The application of heat may facilitate bonding, through metal-metal bonding or solder bonding, such as with the presence of solder tips or solder bumps on either of the contact terminals 121 and/or landing terminals 302. Application of heat can also partially reflow and final cure the photo-definable underfill material 139, providing further adhesion with the receiving substrate and structural stability to transferred sensor dies. After bonding of the portion of the sensor dies 120 to receiving substrate 300A, the vacuum chuck 212 can be withdrawn as shown in FIG. 8 and translated over another receiving substrate 300B as shown in FIG. 9 or to an alternate location over receiving substrate 300B. The placement sequence can then be repeated as shown in FIGS. 10-11A. As shown in FIG. 11A the sensor die 120 includes a plurality of electrical contact terminals 121 bonded to a corresponding plurality of landing terminals 302, where the plurality of electrical contact terminals 121 of the sensor die extend through a thickness of a patterned underfill material 139 that bonds the sensor die to the receiving substrate and defines perimeter edges 151 of the cavity 304 (or space) between the sensor die and the receiving substrate.

Referring specifically to FIG. 11A an enlarged view is provided of a sensor die 120 placed onto landing terminals 302 of a receiving substrate. As shown, each sensor die 120 can include a diaphragm 126 that is deflectable toward a cavity 304 between the sensor die 120 and the receiving substrate. In the particular process sequence illustrated in FIGS. 6-11A the sensor dies 120 can be considered as the sensors 102 described in FIG. 1. Furthermore, the sensor dies 120 can be connected to IC dies 140 as shown in FIG. 2A. In other embodiments, each sensor 102 can include both a sensor die 120 and an IC die 140, for example as shown in FIGS. 2B-2C and FIG. 3. In other embodiments the sensors 102 can be sensor packages including a stacked IC die 140 and sensor die 120, where each sensor die 120 includes a diaphragm that is deflectable toward a cavity between the IC die and the sensor die.

FIGS. 11B-11C are schematic top view illustrations of the diaphragm of an IC die and fractured tethers in accordance with embodiments. As shown, each sensor die 120 can include a plurality of cleaved tether nubs 156 connected to the diaphragm 126 that may be present as a result of the transfer sequence. The cleaved tether nubs 156 may be observable due to being broken during the transfer sequence, as opposed to being patterned during an etching operation (e.g., dry etching operation) or sawing during formation of the sensor dies 120. For example, each diaphragm 126 can include a perimeter edge 158 with a perimeter surface texture (e.g., formed during an etching operation), while each tether nub 156 includes a terminal end 160 with a terminal end surface texture (e.g., formed as a result of fracture) that is different from the perimeter surface texture. The tether nubs 156 may additionally extend away from, or be intended into, the perimeter edge 158.

In the following description various donor substrate structures and process sequences are described for methods of assembly and transferring sensor packages with stacked IC dies and sensor dies in accordance with embodiments.

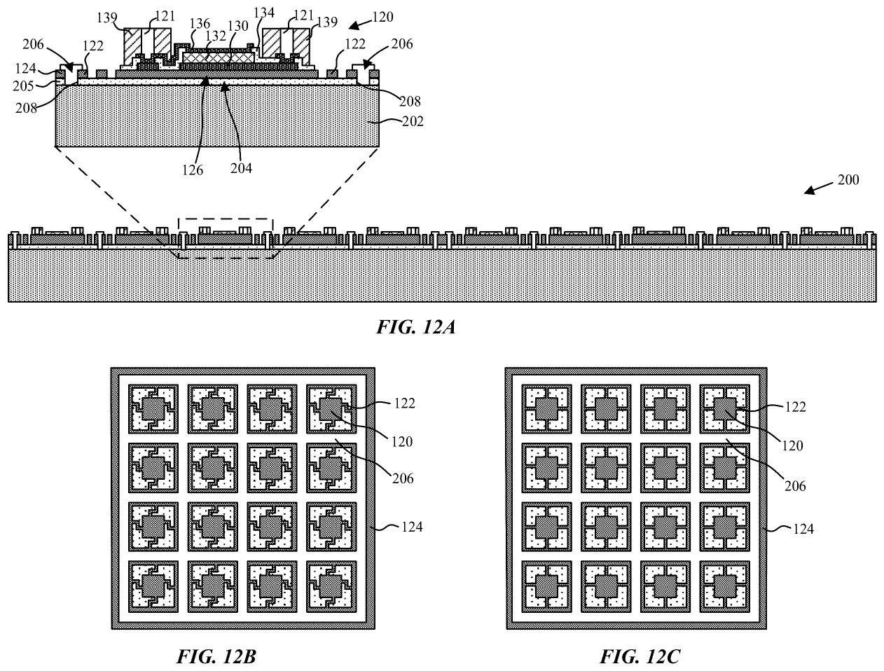

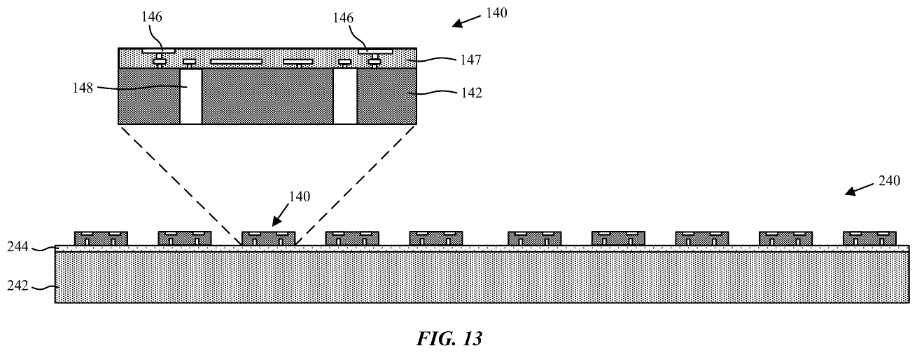

Referring now to FIGS. 12A-12C, FIG. 12A is a schematic cross-sectional side view illustration of a sensor die donor substrate in accordance with an embodiment; FIGS. 12B-12C are schematic top view illustrations of sensor dies supported on a donor substrate with a plurality of tethers in accordance with embodiments. FIGS. 12A-12C are substantially similar to those previously described and illustrated with regard to FIGS. 4A-4C. In interest of clarity and conciseness the previous description related to FIGS. 4A-4C is not repeated and is applicable to that of FIGS. 12A-12C.

FIG. 13 is a schematic cross-sectional side view illustration of an IC die 140 donor substrate 240 in accordance with an embodiment. In the particular embodiment illustrated the IC dies 140 can be adhered to a support substrate 242 formed of a variety of materials, including glass, ceramics, silicon, etc. In accordance with embodiments wafer-level processing with silicon-based wafers can be used to leverage existing equipment and materials systems. For example, the support substrate 242 can be a silicon substrate. A release layer 244, such a polymer or other adhesive, or selectively removable material such as silicon oxide, can be formed over the support substrate 242, and a plurality of IC dies 140 can be secured to the release layer 244. The release layer 244 may be a sacrificial layer that is later removed. The release layer 244 may also be selectively removed relative to the release layer 205 for the sensor dies. The IC dies 140 can include metal oxide semiconductor field effect transistor (MOSFET) implementing circuitry for example, formed within a device layer 142, which may be silicon for example. A back-end-of-the-line (BEOL) build up structure 147 can be formed over the device layer 142 to provide electrical routing, followed by electrical contact terminals 146, which may be formed similarly as electrical contact terminals 121. Through vias, such as through silicon vias (TSVs) 148 can optionally extend through the device layer 142 and any optional additional substrate, such as a base wafer substrate for SOI structure. Device layer 142 may also be a base wafer substrate for example.

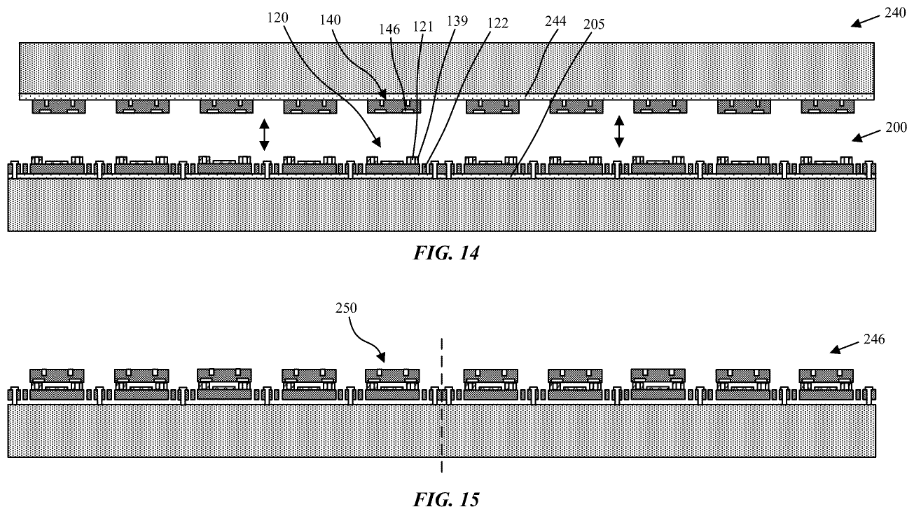

Referring now to FIG. 14 an IC die donor substrate 240 is then bonded to a sensor die donor substrate 200 in accordance with an embodiment. Specifically, the electrical contact terminals 146, 121 can be bonded to one another, for example with metal-metal bonds or using solder tips or micro bumps and application of heat or ultraviolet light. Additionally, the photo-definable wafer-level underfill material 139 can be heated to partially reflow and cure, adhering to both the IC dies 140 and sensor dies 120, and sealing the inner sensor structure.

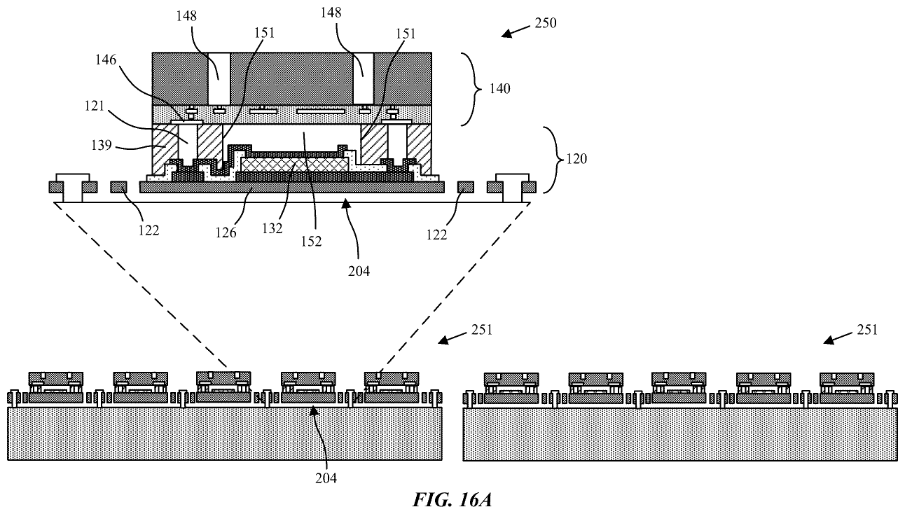

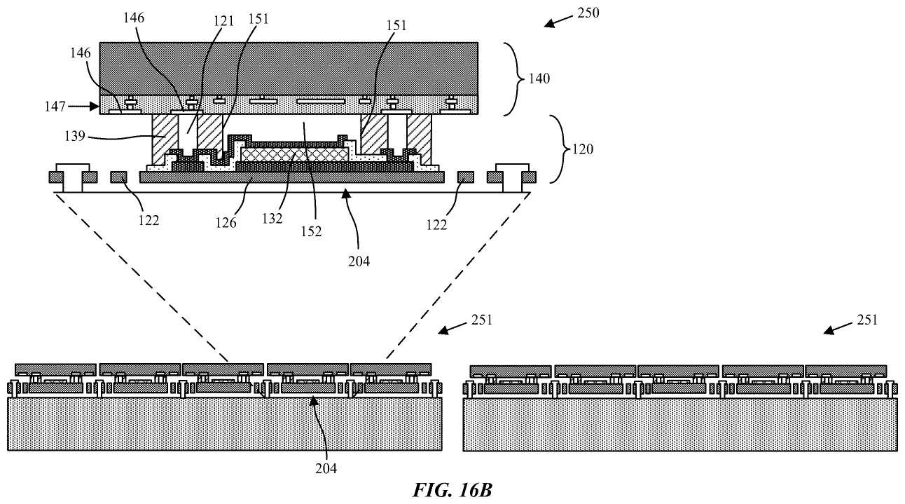

A release process may then be performed to release the IC dies onto the sensor dies. For example, the release operation may be an etch process, heat or radiation activated process, etc. that allows the support substrate 242 to be removed. The release operation may be selective so that release layer 205 is not removed. In accordance with embodiments, after releasing the IC dies 140 onto the sensor dies 120, an etch process may then be performed to remove the release layer 205. For example, a vapor HF operation may be performed to remove release layers 205 and releasing the tethers 122 of the sensor dies 120 as shown in FIG. 15, resulting in a sensor package donor substrate 246. The release operations may also be performed simultaneously, for example, with a vapor HF etch. In some embodiments a protection layer may be formed over the sensor die to protect the tethers during a first (etch) release of the IC dies from the IC donor substrate, followed by removal of the protection layer and an etch release of the tethers of the sensor dies. This may be followed by dicing the sensor package donor substrate into individual sensor package substrates 251, or macro package substrates, as shown in FIG. 16A or FIG. 16B. Alternatively, the release etch operation can be performed after dicing.

FIG. 16B is a schematic cross-sectional side view illustration of a plurality of diced sensor package donor substrates 251 in accordance with an embodiment. FIG. 16B is substantially similar to that of FIG. 16A, with some optional differences in the IC die 140. As shown, the IC die 140 may have a larger footprint (larger area) than the sensor die 120. Additionally, the IC die 140 may not include through vias for backside connection, and instead include additional electrical contact terminals 146 (e.g., landing pads) on the BEOL build-up structure located outside the shadow of the sensor die 120.

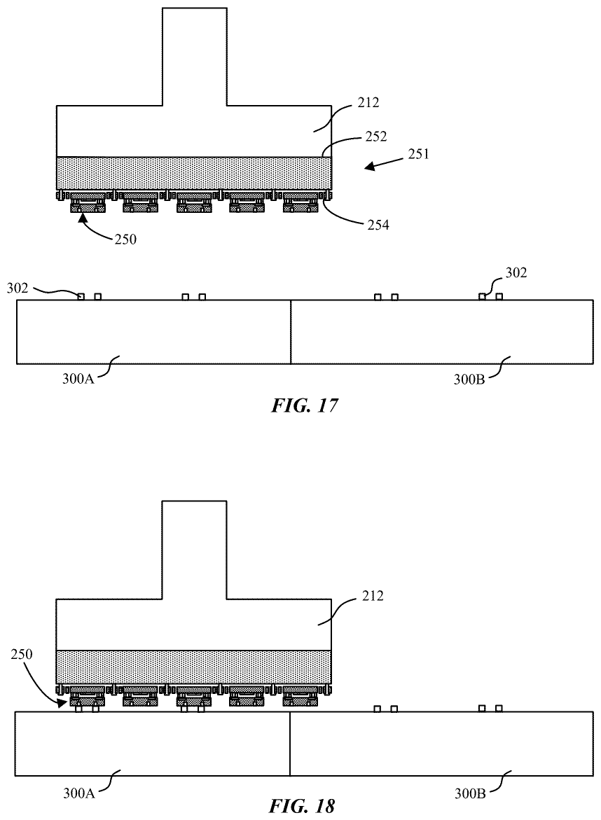

FIGS. 17-22 are schematic cross-sectional side view illustration of a sensor package array transfer sequence in accordance with an embodiment. The transfer sequence may proceed similarly as that previously described with regard to FIGS. 6-11A, with securing a back side 252 of a donor substrate, such as diced donor substrate 251 to a vacuum chuck 212 so that a front side 254 of the donor substrate 251 includes a plurality of sensor packages 250 suspended above a plurality of cavities 204 of the donor substrate 251 with a plurality of tethers 122.

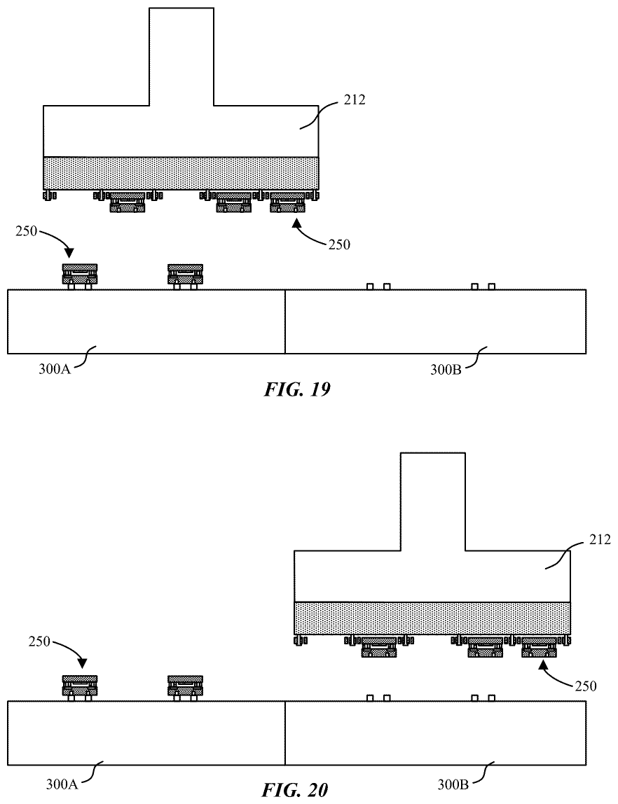

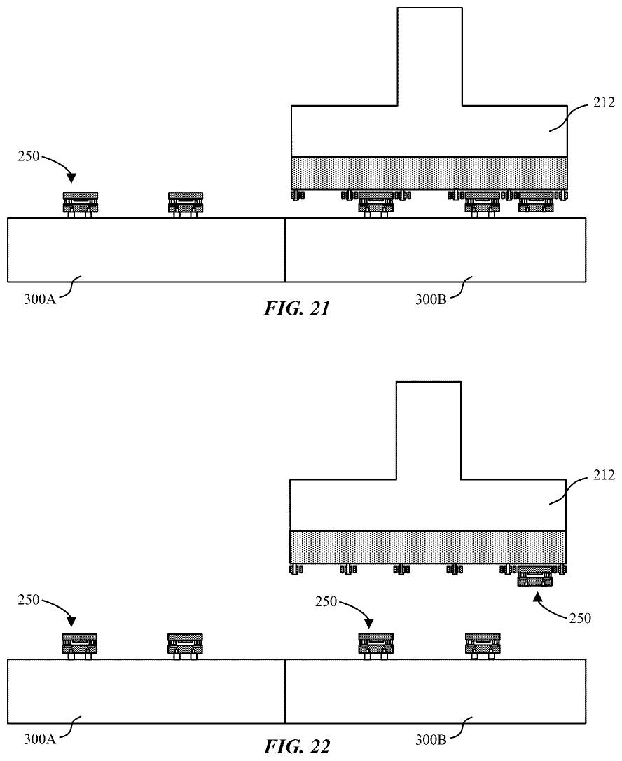

The vacuum chuck 212 can then be translated over a receiving substrate 300A. The receiving substrate 300A is then contacted with at least a portion of the plurality of sensor packages 250. As shown in FIG. 18, the receiving substrate 300A may include a plurality of landing terminals 302 upon which the optional through vias 148 of the IC dies 140 of the sensor packages may be placed to provide electrical connection. While the landing terminals 302 are illustrated as standing proud, the landing terminals 302 can also be flush with a top surface of the receiving substrate 300A, for example as shown in FIGS. 6-11A. Additionally, only a portion of the sensor packages 250 may be contacted with the receiving substrate 300A. In accordance with embodiments, pressure applied by the vacuum chuck 212 and opposing force pressure of the receiving substrate 300A can cause the plurality of tethers 122 connected to the contacted sensor dies 120 of the sensor packages 250 to break, releasing the portion of the plurality of sensor packages 250 onto the receiving substrate 300A. This may be accompanied by the application of heat to the donor substrate 201 while contacting the receiving substrate with the plurality of sensor packages. For example, this can be with a heater connected to the vacuum chuck 212. Heat may also be applied through the receiving substrate 300A, or from an alternative source. The application of heat may facilitate bonding, through metal-metal bonding or solder bonding, such as with the presence of solder tips or solder bumps on either of the through vias 148 and/or landing terminals 302. After bonding of the portion of the sensor packages 250 to receiving substrate 300A, the vacuum chuck 212 can be withdrawn as shown in FIG. 19 and translated over another receiving substrate 300B as shown in FIG. 20 or to an alternate location over receiving substrate 300B. The placement sequence can then be repeated as shown in FIG. 21 and FIG. 22.

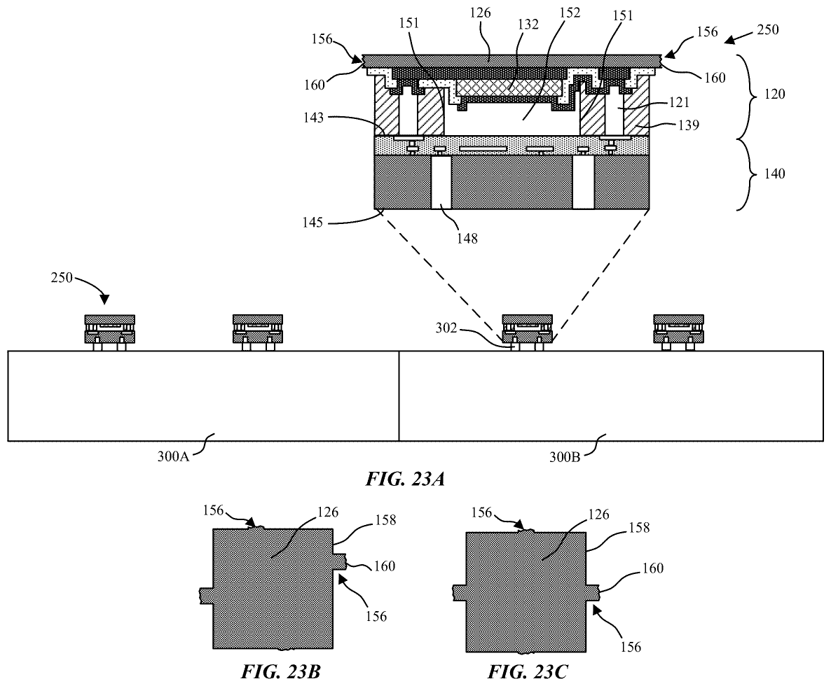

Referring specifically to FIG. 23A, an enlarged view is provided of a sensor package 250 placed onto landing terminals 302 of a receiving substrate. FIGS. 23B-23C are schematic top view illustrations of the diaphragm 126 of an IC die 120 of a sensor package and fractured tethers 122 in accordance with embodiments. Specifically, the top view illustrations of FIGS. 23B-23C correspond to the previous tether configurations shown in FIGS. 12B-12C.

In an embodiment a sensor assembly includes an article 106 (see FIG. 1), and a sensor array 104 coupled with the article, the sensor array including a plurality of sensor packages 250. As shown in FIG. 23A, each sensor package 250 can include an IC die 140 including a top side 143 and a back side 145, and a sensor die 120 bonded to the top side 143 of the IC die 140. The sensor die 120 can include a diaphragm 126 that is deflectable toward a cavity 152 between the IC die 120 and the sensor die 120. Similar to previous discussion, the sensor die 120 can include a strain response material layer 132 on the diaphragm 126 and between the diaphragm 126 and the IC die 140. The IC die 140 may for example include AFE circuitry to amplify and filter analog signals derived from the strain response material layer 132 upon deflection of the diaphragm 126; and an ADC. The IC die 140 may additionally include address circuitry to define a unique address of the sensor package 250.

As shown, each sensor die 120 can include a plurality of cleaved tether nubs 156 connected to the diaphragm 126 that may be present as a result of the transfer sequence. The cleaved tether nubs 156 may be observable due to being broken during the transfer sequence, as opposed to being patterned during an etching operation (e.g., dry etching operation) or sawing during formation of the sensor dies 120. For example, each diaphragm 126 can include a perimeter edge 158 with a perimeter surface texture (e.g., formed during an etching operation), while each tether nub 156 includes a terminal end 160 with a terminal end surface texture (e.g., formed as a result of fracture) that is different from the perimeter surface texture. The tether nubs 156 may additionally extend away from, or be intended into, the perimeter edge 158.

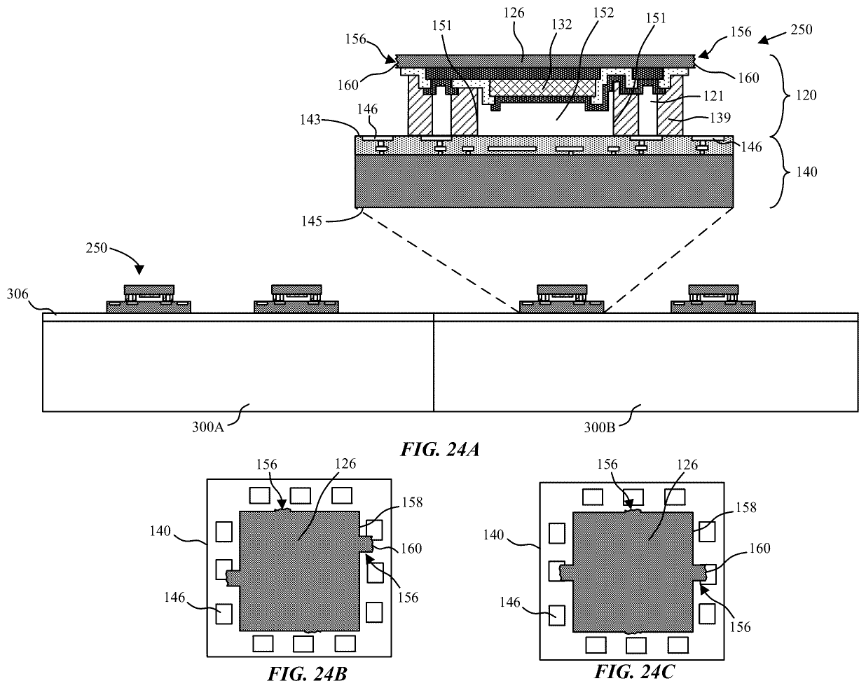

FIG. 24A is schematic cross-sectional side view illustration of sensor package with fractured tethers and face up IC die in accordance with embodiments. FIGS. 24B-24C are schematic top view illustrations of the diaphragm and fractured tethers of a sensor die superimposed over an IC die of a sensor package in accordance with embodiments. As shown, the back sides 145 of the IC dies 140 may be placed onto an adhesive layer 306, or other support layer, on the one or more receiving substrates during the transfer sequence. In such a configuration, electrical contact to the exposed electrical contact terminals 146 outside the shadow of the sensor die 120 can be made after the transfer sequence. As shown in both FIG. 23A and FIG. 24A the sensor die 120 includes a plurality of electrical contact terminals 121 bonded to a corresponding plurality of electrical contact terminals 146 of the IC die, where the plurality of electrical contact terminals 121 of the sensor die extend through a thickness of a patterned underfill material 139 that bonds the sensor die to the IC die and defines perimeter edges 151 of the cavity 152 between the sensor die and the IC die. In the embodiment illustrated in FIG. 24A a second plurality of electrical contact terminals 146 (e.g., landing pads) of the IC die can be located laterally outside of patterned underfill material 139. Additionally, the IC die may have a larger footprint than the sensor die.

In utilizing the various aspects of the embodiments, it would become apparent to one skilled in the art that combinations or variations of the above embodiments are possible for assembling and transferring arrays of sensors. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A sensor assembly comprising:
an article;
a sensor array coupled with the article, the sensor array including a plurality of sensor packages, each sensor package including:
an integrated circuit (IC) die including a top side and a back side; and
a sensor die bonded to the top side of the IC die;
wherein the sensor die includes a diaphragm that is deflectable toward a cavity between the IC die and the sensor die.

2. The sensor assembly of claim 1, wherein the sensor die comprises a strain response material layer on the diaphragm, and between the diaphragm and the IC die.

3. The sensor assembly of claim 2, wherein the IC die comprises:
analog front end (AFE) circuitry to amplify and filter analog signals derived from the strain response material layer upon deflection of the diaphragm; and
an analog to digital converter (ADC).

4. The sensor assembly of claim 2, wherein the sensor die includes a plurality of electrical contact terminals bonded to a corresponding plurality of electrical contact terminals of the IC die, wherein the plurality of electrical contact terminals of the sensor die extend through a thickness of a patterned underfill material that bonds the sensor die to the IC die and defines perimeter edges of the cavity between the IC die and the sensor die.

5. The sensor assembly of claim 4, further comprising a second plurality of electrical contact terminals of the IC die, wherein the second plurality of contact terminals is laterally outside of the patterned underfill material.

6. The sensor assembly of claim 5, wherein the IC die has a larger footprint than the sensor die.

7. The sensor assembly of claim 3, wherein each sensor die includes a plurality of cleaved tether nubs connected to the diaphragm.

8. The sensor assembly of claim 7, wherein each diaphragm includes a perimeter edge, and perimeter surface texture spanning the perimeter edge, and each tether nub includes a terminal end with a terminal end surface texture different from the perimeter surface texture.

9. The sensor assembly of claim 3, wherein the sensor assembly is coupled to an article of a wearable system.

10. A donor substrate comprising:
a support substrate including a pattern of anchors, and a plurality of cavities with cavity sidewalls defined by the pattern of anchors;
a plurality of sensors suspended over the plurality of cavities;
a plurality of tethers extending from the plurality of sensors and connected to the pattern of anchors to suspend the plurality of sensors over the plurality of cavities.

11. The donor substrate of claim 10, further comprising a support layer spanning over the support substrate, the support layer comprising an array of diaphragms and the plurality of tethers, wherein each sensor includes a diaphragm of the array of diaphragms.

12. The donor substrate of claim 11, wherein the support layer comprises silicon.

13. The donor substrate of claim 11, wherein each sensor comprises a strain response material layer over a corresponding diaphragm.

14. The donor substrate of claim 13, further comprising a plurality of electrical contact terminals protruding away from the diaphragm, wherein the plurality of electrical contact terminals protrude above the strain response material layer.

15. The donor substrate of claim 14, further comprising a patterned underfill material on the diaphragm and laterally surrounding the strain response material layer and the plurality of electrical contact terminals.

16. A sensor array transfer sequence comprising:
securing a back side of a donor substrate to a vacuum chuck;
wherein a front side of the donor substrate comprises a plurality of sensors suspended above a plurality of cavities in the donor substrate with a plurality of tethers;
translating the vacuum chuck over a receiving substrate;
contacting the receiving substrate with the plurality of sensors; and
breaking the plurality of tethers to release the plurality of sensors onto the receiving substrate.

17. The sensor array transfer sequence of claim 16, wherein each sensor comprises a sensor die and an integrated circuit (IC) die.

18. The sensor array transfer sequence of claim 17, wherein each sensor die includes a diaphragm that is deflectable toward a cavity between the IC die and the sensor die.

19. A method of forming a sensor array comprising:
bonding an array of integrated circuit (IC) dies supported on an IC die donor substrate to a plurality of sensor dies supported on a sensor die donor substrate;
releasing the plurality of IC dies onto the plurality of sensor dies; and
etching a release layer on the sensor die donor substrate to remove the release layer from a plurality of cavities underneath the plurality of sensor dies.

20. The method of claim 19, wherein etching the release layer comprises a vapor etch process.
